(19) United States
(12) Patent Application Publication
(10) Pub. No.: US 2025/0089344 A1
(43) Pub. Date: Mar. 13, 2025

(54) THIN FILM TRANSISTOR AND PREPARATION METHOD THEREOF, DISPLAY PANEL, AND DISPLAY DEVICE

(71) Applicants: Yungu (Gu’an) Technology Co., Ltd., Langfang (CN); Hefei Visionox Technology Co., Ltd., Hefei (CN)

(72) Inventors: Xiaoqi SUN, Langfang (CN); Guowen YAN, Langfang (CN); Lidong DING, Langfang (CN); Fa-Hsyang CHEN, Langfang (CN); Lin XU, Langfang (CN); Dejian WANG, Langfang (CN)

(73) Assignees: Yungu (Gu’an) Technology Co., Ltd., Langfang (CN); Hefei Visionox Technology Co., Ltd., Hefei (CN)

(21) Appl. No.: 18/958,379

(22) Filed: Nov. 25, 2024

(30) Foreign Application Priority Data
Nov. 30, 2023 (CN) 202311631979.8

(51) Int. Cl. H01L 29/51; H01L 21/28; H01L 27/12; H01L 29/24; H01L 29/66; H01L 29/786

(52) U.S. Cl. CPC H10D 64/685; H01L 21/28008; H10D 30/031; H10D 30/6755; H10D 62/80; H10D 86/423; H10D 86/60

(57) ABSTRACT

A thin film transistor and a preparation method thereof, a display panel, and a display device. The thin film transistor includes an active structure and a gate that are stacked and insulated by an interlayer insulating layer, the active structure includes a source region, a drain region, and a channel region, the source region and the drain region are located on two sides of the channel region, and in a thickness direction of the interlayer insulating layer, a projection of the gate overlaps with a projection of the channel region; wherein the channel region includes a metal oxide material, a ratio of a number of indium atoms and a number of zinc atoms in the channel region is a, and a≥4.

### CROSS REFERENCE TO RELATED APPLICATION

The present application claims priority to Chinese Patent Application No. 202311631979.8 filed on Nov. 30, 2023, and titled “THIN FILM TRANSISTOR AND PREPARATION METHOD THEREOF, DISPLAY PANEL, AND DISPLAY DEVICE”, which is incorporated herein by reference in its entirety.

### TECHNICAL FIELD

The present application relates to the technical field of display device, and particularly to a thin film transistor and a preparation method thereof, a display panel, and a display device.

### BACKGROUND

As an important electrical device in the display device, the performance of the thin film transistor directly affects the display effect and service life of the display device. How to improve the migration rate of the active structure in the thin film transistor has become an urgent problem to be solved now.

### SUMMARY

Embodiments of the present application provide a thin film transistor and a preparation method thereof, a display panel, and a display device, which can improve reliability.

In a first aspect, the embodiments of the present application provide a thin film transistor including an active structure and a gate that are stacked and insulated by an interlayer insulating layer, the active structure including a source region, a drain region, and a channel region, the source region and the drain region being located on two sides of the channel region, and in a thickness direction of the interlayer insulating layer, a projection of the gate overlapping with a projection of the channel region; wherein the channel region includes a metal oxide material, a ratio of a number of indium atoms and a number of zinc atoms in the channel region is a, and a≥4.

In a second aspect, the embodiments of the present application provide a display panel including the thin film transistor described in any of the above embodiments.

In a third aspect, the embodiments of the present application provide a display device including the display panel described in any of the above embodiments.

In a fourth aspect, the embodiments of the present application provide a preparation method for a thin film transistor, including:
forming an interlayer insulating layer on a side of an active structure, the active structure including a source region, a drain region, and a channel region, the source region and the drain region being located on two sides of the channel region, the channel region including a metal oxide material, and a ratio of a number of indium atoms and a number of zinc atoms in the channel region is a, and a≥4;
forming a gate on a side of the interlayer insulating layer away from a substrate, and in a thickness direction of the interlayer insulating layer, a projection of the gate overlapping with a projection of the channel region.

According to the thin film transistor and the preparation method thereof, the display panel, and the display device provided by the embodiments of the present application, by setting a as not less than 4, the number of the indium atoms in the channel region is increased, and thus the number of movable carriers is increased, so that the channel region has a relative high carrier concentration. Further, on the basis of high carrier concentration, the carrier migration rate in the active structure is improved, and thus the overall performance of the thin film transistor is improved.

### BRIEF DESCRIPTION OF THE DRAWINGS

In order to clearly illustrate the technical solutions of the embodiments of the present application, the accompanying drawings used in the embodiments are briefly described below. For those of ordinary skill in the art, other relevant drawings can also be obtained without creative efforts according to these accompanying drawings.

FIG. 1 is a schematic sectional structural view of a thin film transistor provided by the embodiments of the present application;

FIG. 2 is a schematic sectional structural view of another thin film transistor provided by the embodiments of the present application;

FIG. 3 is a schematic sectional structural view of another thin film transistor provided by the embodiments of the present application;

FIG. 4 is a schematic sectional structural view of a display device provided by the embodiments of the present application;

FIG. 5 is a flowchart of a preparation method for a thin film transistor provided by the embodiments of the present application;

FIG. 6A to FIG. 6B are schematic structural views of a process of a preparation method for a thin film transistor provided by the embodiments of the present application;

FIG. 7 is a flowchart of a preparation method for a thin film transistor provided by the embodiments of the present application;

FIG. 8A to FIG. 8B are schematic structural views of a process of a preparation method for a thin film transistor provided by the embodiments of the present application.

### REFERENCE NUMERALS

T, thin film transistor;
10, active structure;
20, gate; 21, first sub-gate; 22, second sub-gate;
31, source; 32, drain;
40, interlayer insulating layer; 41, first insulating layer; 42, second insulating layer;
50, substrate;
A1, channel region; A2, source region; A3, drain region.

### DETAILED DESCRIPTION

Features and exemplary embodiments of various aspects of the present application will be described in detail below. In order to make the objects, technical solutions and advantages of the present application clearer, the present application is further described in detail below with reference to the accompanying drawings and specific embodiments. It should be understood that the specific embodiments described herein are only used to explain the present application, but not to limit the present application. For those skilled in the art, the present application can be implemented without some of these specific details. The following description of the embodiments is only to provide a better understanding of the present application by illustrating examples of the present application.

It should be noted that, in the present application, relational terms, such as first and second, are used merely to distinguish one entity or operation from another entity or operation, without necessarily requiring or implying any actual such relationships or orders for these entities or operations. Moreover, the terms “include”, “include”, or any other variants thereof, are intended to represent a non-exclusive inclusion, such that a process, method, article or device including a series of elements includes not only those elements, but also other elements that are not explicitly listed or elements inherent to such a process, method, article or device. Without more constraints, the elements following an expression “include/include . . . ” do not exclude the existence of additional identical elements in the process, method, article or device that includes the elements.

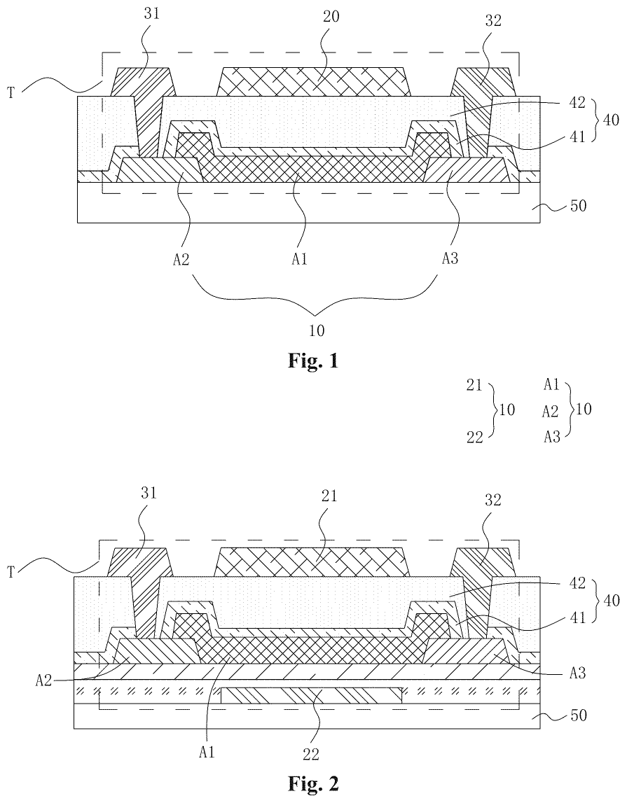

In a first aspect, please refer to FIG. 1. The embodiments of the present application provide a thin film transistor T including an active structure 10 and a gate 20 that are stacked and insulated by an interlayer insulating layer 40, the active structure 10 including a source region A2, a drain region A3, and a channel region A1, the source region A2 and the drain region A3 being located on two sides of the channel region A1, and in a thickness direction of the interlayer insulating layer 40, a projection of the gate 20 overlapping with a projection of the channel region A1. Here, the channel region A1 includes a metal oxide material, a ratio of a number of indium atoms and a number of zinc atoms in the channel region A1 is a, and a≥4.

The thin film transistor T is an insulating gate field effect transistor mainly composed of a conductor structure, a semiconductor structure, and an insulating structure located between them. The conductor structure includes a gate 20, a source 31 and a drain 32, the semiconductor structure includes an active structure 10, the active structure 10 and the gate 20 are separated by the interlayer insulating layer 40, the source 31 and the drain 32 can be located in the same film layer, and the source 31 and the drain 32 can be separated from the active structure 10 by an insulating layer. The active structure 10 includes the source region A2, the drain region A3, and the channel region A1, and the source region A2 and the drain region A3 are located on two sides of the channel region A1. Here, the source 31 and the source region A2 in the active structure 10 are electrically connected by vias, and the drain 32 and the drain region A3 in the active structure 10 are electrically connected by vias. The embodiment of the present application does not limits the material of the gate 20, source 31 and drain 32. Optionally, the gate 20, the source 31, and the drain 32 include a conductive metal such as metal molybdenum.

It should be noted that, depending on the actual needs, the interlayer insulating layer 40 between the active structure 10 and the gate 20 may include only one insulating layer, or may include two insulating layers that are stacked, which is not limited by the embodiments of the present application.

In the thickness direction of the interlayer insulating layer 40, the projection of the gate 20 overlaps with the projection of the channel region A1. After applying a voltage to the gate 20, a carrier migration channel is formed in the active structure 10. Specifically, when the thin film transistor T operating, a voltage is applied to the gate 20, and an electric field is generated. The direction of the electric field is from the gate 20 to the surface of the channel region A1 of the active structure 10, and an induced charge is generated at the surface. As the voltage of gate 20 increases, the surface of channel region A1 will change from a depletion layer to an electron accumulation layer, thereby forming an inversion layer. When the voltage of the gate 20 reaches the threshold voltage, a voltage will be applied between the source region A2 and the drain region A3, and carriers will pass through the channel region A1.

Further, the migration rate is an important measure of the motility of the carriers in the active structure 10, and the size of the migration rate plays a decisive role in the performance of the thin film transistor T. High migration rate means that the electrons or holes in the active structure 10 move more rapidly and can respond to external signals more quickly, thereby improving the working speed and performance of the device. In other words, the size of the migration rate directly affects the switching speed, current driving ability and current transmission efficiency of the thin film transistor T. The higher the migration rate, the faster the switching speed, the stronger the current driving ability, and the higher the current transmission efficiency of the thin film transistor T.

There are many factors affecting the migration rate, such as material factors, temperature factors, doping factors and structural factors. Here, the selection of materials will have an important impact on the migration rate. On this basis, the embodiments of the present application adjust the material composition in the channel region A1, so that the ratio a of the number of indium atoms and the number of zinc atoms is not less than 4. Here, the ratio a of the number of indium atoms and the number of zinc atoms refers to the value of the number of indium atoms divided by the number of zinc atoms. Optionally, the values of a can be 4, 4.5, 5, 6, 8, and the like. Further optionally, a≥6.

In the related art, the ratio of the number of indium atoms and the number of zinc atoms is usually close to 1, but in the embodiments of the present application, by setting a as not less than 4, the number of the indium atoms in the channel region A1 is increased, and thus the number of movable carriers is increased, so that the channel region A1 can have a relative high carrier concentration. Further, on the basis of high carrier concentration, the carrier migration rate in the active structure 10 is improved, and thus the overall performance of the thin film transistor T is improved.

It should be noted that, depending on different requirements, the thin film transistor T in the embodiments of the present application may be selectively provided with gallium atoms, that is, the channel region A1 may include indium gallium zinc oxide (IGZO). Alternatively, no gallium atom is provided, that is, the channel region A1 may include indium zinc oxide (IZO).

In some embodiments, as shown in FIG. 1, the interlayer insulating layer 40 includes a first insulating layer 41 and a second insulating layer 42 sequentially stacked in a direction away from the active structure 10, and a content of hydrogen atoms in the first insulating layer 41 is b, and b≥5%.

The interlayer insulating layer 40 includes at least two kinds of insulating layers: the first insulating layer 41 and the second insulating layer 42. The first insulating layer 41 is disposed closer to the active structure 10 than the second insulating layer 42. Here, the first insulating layer 41 may be disposed as directly contacting the active structure 10, or the first insulating layer 41 and the active structure 10 may be spaced from each other. Optionally, the first insulating layer 41 is disposed as directly contacting the active structure 10, and the reference to the directly contacting refers to the first insulating layer 41 being close to and contacting the active structure 10.

Since the first insulating layer 41 is disposed closer to the active structure 10, the preparation of the first insulating layer 41 may easily influence the active structure 10 during the preparation. On this basis, under a condition that the first insulating layer 41 is formed at high temperature, a part of the indium atoms in the channel region A1 may be easily reduced and precipitated on the surface of the active structure 10.

In view of this, the embodiments of the present application change the preparation method of the first insulating layer 41, so as to form the first insulating layer 41 at low temperature. Generally, the lower the preparation temperature, the higher the content of hydrogen atoms in the formed membrane layer. Therefore, at the low temperature, the first insulating layer will have a higher concentration of hydrogen atoms. Here, the content b of the hydrogen atoms in the first insulating layer 41 is not less than 5%. The content b of the hydrogen atoms mentioned here refers to the percentage of the number of hydrogen atoms to the total number of atoms in the first insulating layer 41. Optionally, the value of b can be 5%, 7%, 10%, 15%, and the like.

This design helps to reduce the influence of the preparation process corresponding to the first insulating layer 41 on the active structure 10, so as to reduce the risk of precipitation of the indium atoms on the surface of the active structure 10, and reduce the risk of carrier interface scattering. Further, a certain hydrogen content also helps to regulate the number of carriers in the channel region A1, and improve the service reliability of the thin film transistor T.

It should be noted that, in addition to the first insulating layer 41 and the second insulating layer 42, the interlayer insulating layer 40 may include other insulating layers or may not include other insulating layers, which is not limited by the embodiments of the present application.

In some embodiments, b≤10%. Optionally, the value of b can be 5%, 7%, 9%, 10%, and the like.

From the foregoing, in order to reduce the risk of precipitation of the indium atoms on the surface of the active structure 10, the first insulating layer 41 is formed at a relatively low temperature, so that the content b of the hydrogen atoms in the first insulating layer 41 is not less than 5%. On this basis, under a condition that the content b of the hydrogen atoms is too high, it is easy to affect the off current corresponding to the thin film transistor T, which is not conducive to the normal use of the thin film transistor T. In view of this, the embodiments of the present application also sets the content b of the hydrogen atoms in the first insulating layer 41 as not large than 10%, so as to reduce the influence of the excessive hydrogen content on the thin film transistor T, and improve the service reliability of the thin film transistor T.

In some embodiments, a thickness of the first insulating layer 41 is H1, and 5 nm<H1≤20 nm. Optionally, the thickness H1 of the first insulating layer 41 can be 5 nm, 7 nm, 10 nm, 15 nm, 20 nm, and the like.

In the embodiments of the present application, the first insulating layer 41 can be formed by low temperature preparation, which can improve indium reduction effect. Further, providing a certain amount of hydrogen atoms can repair the channel interface defect. On this basis, corresponding to the relative small thickness of the thin film, the device characteristics can be optimized, the migration rate can be improved, and the stability can be ensured, which has strong practicability.

It should be noted that the specific material composition of the first insulating layer 41 is not limited by the embodiments of the present application. Optionally, the first insulating layer 41 includes at least one of silicon oxide and aluminum oxide.

In some embodiments, a density of the first insulating layer 41 is less than a density of the second insulating layer 42. Here, the density refers to the number of atoms per unit volume.

In practical application, in addition to the performance index of the thin film transistor T, it is also necessary to consider the stability of the thin film transistor T. The density of the interlayer insulating layer 40 between the gate 20 and the active structure 10 may have some influence on the stability of the thin film transistor T. Here, the density can usually reflect the blocking ability of the membrane layer for gas. The higher the density, the stronger the blocking ability of the membrane layer for gas; and the lower the density, the weaker the blocking ability of the membrane layer for gas.

Further, under a condition that the densities at all the positions of the interlayer insulating layer 40 is low, the water vapor and harmful substances can penetrate into the active structure 10 via the interlayer insulating layer 40 during subsequent membrane layer preparation, resulting in the problems that the characteristics of the thin film transistor T are degraded, the driving voltage is unstable, and the life span of the thin film transistor is greatly reduced.

In view of this, in the embodiments of the present application, on the basis of the first insulating layer 41, the second insulating layer 42 is added in the interlayer insulating layer 40. Compared with the first insulating layer 41, the second insulating layer 42 can have a better density, and the second insulating layer 42 can have a good blocking effect to reduce the risk of the water vapor and harmful substances penetrating into the active structure 10 via the second insulating layer 42 during subsequent membrane layer preparation, thereby improving the stability of the thin film transistor T, and improving the service life of the thin film transistor T.

It should be noted that the density can be affected by multiple factors. For example, during preparation, the second insulating layer 42 can be formed under high temperature condition, so that the second insulating layer 42 can have a higher density. At the same time, since the first insulating layer 41 is located between the second insulating layer 42 and the active structure 10, in the preparation of the second insulating layer 42, the first insulating layer 41 can reduce the risk of the indium atoms precipitating on the surface of the active structure 10 under the high temperature condition. So that, the thin film transistor T can have a higher migration rate while the stability of the thin film transistor T is improved, thereby improving the driving performance of the thin film transistor T.

In some embodiments, a content of hydrogen atoms in the second insulating layer 42 is c, and c≤5%.

In the embodiments of the present application, the second insulating layer 42 may be formed by high temperature film formation, so that the content c of hydrogen atoms in the second insulating layer 42 is not more than 5%. The content c of hydrogen atoms mentioned here refers to the percentage value of the number of hydrogen atoms to the total number of atoms in the second insulating layer 42. Optionally, the value c of can be 0%, 1%, 3%, 5%, and the like. In this design, the second insulating layer 42 has both a higher density and a lower hydrogen atomic content, which helps to further improve the stability of the thin film transistor T and helps to improve the service life of the thin film transistor T.

It should be noted that the specific material composition of the second insulating layer 42 is not limited by the embodiments of the present application. Optionally, the second insulating layer 42 includes at least one of aluminum oxide and hafnium dioxide, so that the second insulating layer 42 may have a higher dielectric constant. Here, the dielectric constant has an important influence on the thin film transistor T, and the thin film transistor T can use the dielectric response characteristics of the second insulation layer 42 to adjust and control the electric signal under the action of applied electric field. Therefore, the second insulating layer 42 with high dielectric constant helps to improve the overall stability of the thin film transistor T.

In some embodiments, a thickness of the second insulating layer 42 is H2, and 80 nm ≤H2≤200 nm. Optionally, H2 can be 80 nm, 100 nm, 120 nm, 150 nm, 200 nm, and the like.

The second insulating layer 42 in the embodiments of the present application has a large thickness and a high density, which helps to improve the protective effect of the second insulating layer 42 on the active structure 10, and further reduce the risk of the water vapor and harmful substances penetrating into the active structure 10 via the second insulating layer 42 during subsequent membrane layer preparation, thereby improving the stability of the thin film transistor T.

In some embodiments, the channel region A1 further includes a plurality of X atoms, the X atoms are metal atoms, and a ratio of a number of the X atoms and the number of the indium atoms is d, and d≤0.1. Optionally, d can be 0, 0.001, 0.01, 0.05, 0.1, and the like.

The X atoms are metal atoms other than indium atoms and zinc atoms. The plurality of X atoms can be all the same metal atoms, or some X atoms can also be different metal atoms. The specific type and number of X atoms are not limited by the embodiments of the present application. Optionally, the plurality of X atoms include at least one of gallium atoms, tin atoms, tantalum atoms, and tungsten atoms.

Through experiments, the applicant found that when the content of other metal elements such as gallium atoms in the channel region A1 is too high, it will also have a bad effect on the migration rate of the thin film transistor T. In view of this, the content of X atoms is limited by the embodiments of the present application, so that the ratio of the number of the X atoms and the number of the indium atoms is not greater than 0.1, thereby helping to improve the migration rate of the thin film transistor T, and enabling high performance strength of the thin film transistor T. Further, a small number of X atoms may also help to improve the overall structural stability of the thin film transistor.

Optionally, a ratio of the number of the X atoms and the number of the zinc atoms is e, and e≤0.5.

In a second aspect, the embodiments of the present application provide a display panel including the thin film transistor T described in any of the above embodiments.

It should be noted that the display panel provided by the embodiments of the present application has the beneficial effect of the thin film transistor T in any of the aforementioned embodiments, as detailed in the above description of the beneficial effect of thin film transistor T, which will not be repeated by the embodiments of the present application.

Further, the thin film transistor T in the display panel provided by the embodiments of the present application may have a variety of structural types, such as a top-gate thin film transistor T, or a bottom-gate thin film transistor T, or a double-gate thin film transistor T, which is not limited by the embodiments of the present application.

In some alternative embodiments, as shown in FIG. 1, the display panel includes a substrate 50 and a thin film transistor T, the thin film transistor T is disposed on a side of the substrate 50, and the gate 20 is disposed on a side of the active layer away from the substrate 50. That is, the thin film transistor T provided by the embodiments of the present application may be a top-gate thin film transistor T.

The substrate 50 mainly plays the role of supporting load, and the other membrane layers are sequentially stacked on the substrate 50. Here, the “stacked” mentioned here refers to that the other membrane layers are arranged in sequence along the thickness direction of the substrate 50, and the thickness directions of the other membrane layers located on a side of the substrate 50 is generally consistent with the thickness direction of the substrate 50 itself.

The gate 20 is disposed on the side of the active layer away from the substrate 50. During preparation, the active structure 10 is usually formed on the side of the substrate 50 firstly, and then the first insulating layer 41, the second insulating layer 42, the gate 20, the source 31 and the drain 32 are successively formed on the active structure 10. In this process, the first insulating layer 41 is formed next to the active structure 10, and the first insulating layer 41 can cover and protect at least part of the active structure 10, thereby reducing, in the preparation process of the second insulating layer 42, the adverse effects of the preparation process corresponding to the second insulating layer 42 on the active structure 10, and improving the preparation yield and reliability. Also, the second insulating layer 42 formed by the preparation can also cover and protect the active structure 10, thereby reducing the influence of the subsequent manufacturing process on the active structure 10, and improving the preparation yield and reliability.

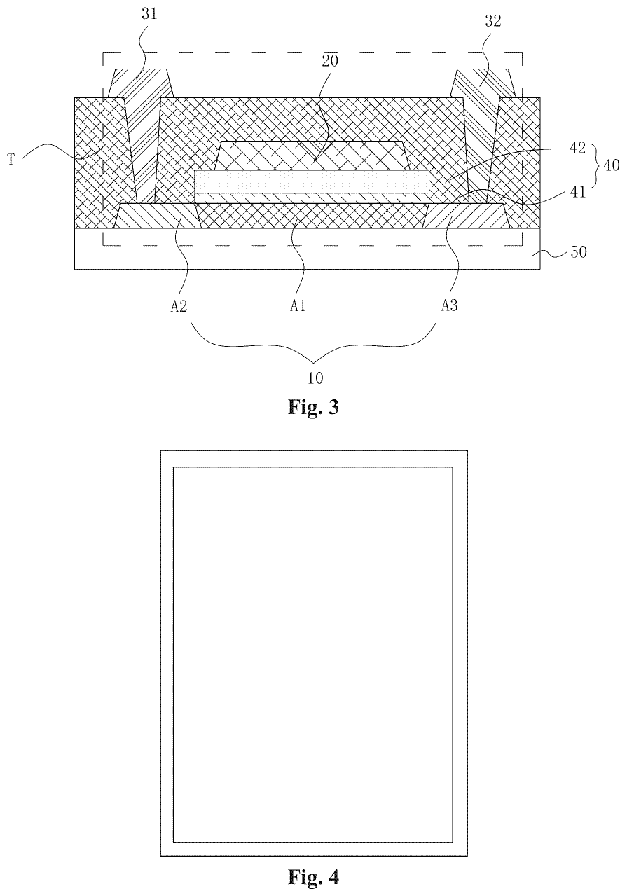

It should be noted that, in addition to the structure shown in FIG. 1, the thin film transistor T provided by the embodiments of the present application may also be the structure shown in FIG. 3. Here, in FIG. 1, the drain 32 and the source 31 are arranged in the same layer as the gate 20, while in FIG. 3, the drain 32 and the source 31 are located on the side of the gate 20 away from the substrate 50. Furthermore, there may be some differences between the first insulating layer 41 and the second insulating layer 42 in FIG. 1 and the first insulating layer 41 and the second insulating layer 42 in FIG. 3.

Alternatively, in other embodiments, referring to FIG. 2, the gate 20 includes a first sub-gate 21 and a second sub-gate 22 respectively arranged on two sides of the active structure 10 in the thickness direction of the substrate 50, and an orthographic projection of the first sub-gate 21 on the substrate 50 and an orthographic projection of the second sub-gate 22 on the substrate 50 both overlap with an orthographic projection of the same channel region A1 on the substrate 50. That is, the thin film transistor T provided by the embodiment of the present application may be a double-gate thin film transistor T.

The first sub-gate 21 and the second sub-gate 22 are respectively located on two sides of the active structure 10, one is used as the top gate, and the other is used as the bottom gate. Here, the orthographic projection of the first sub-gate 21 on the substrate 50 and the orthographic projection of the second sub-gate 22 on the substrate 50 both overlap with the orthographic projection of the same channel region A1 on the substrate 50, so that the first sub-gate 21 and the second sub-gate 22 can jointly control the channel region A1 in the same active structure 10. Here, two insulating layers may be stacked between the first sub-gate 21 and the active structure 10, and two insulating layers may be stacked between the second sub-gate 22 and the active structure 10.

In the embodiments of the present application, by setting the double-gate thin film transistor T, it helps in greatly increasing the carrier migration rate of the thin film transistor T, solving the threshold voltage drift problem of the thin film transistor T, and achieving the effect of improving the electrical performance stability of the thin film transistor T.

In a third aspect, referring to FIG. 4, the embodiments of the present application provide a display device including the display panel described in any of the above embodiments.

It should be noted that the display device provided by the embodiments of the present application has the beneficial effect of the display panel in any of the aforementioned embodiments, as detailed in the above description of the beneficial effect of the display panel and the thin film transistor T, which will not be repeated by the embodiments of the present application.

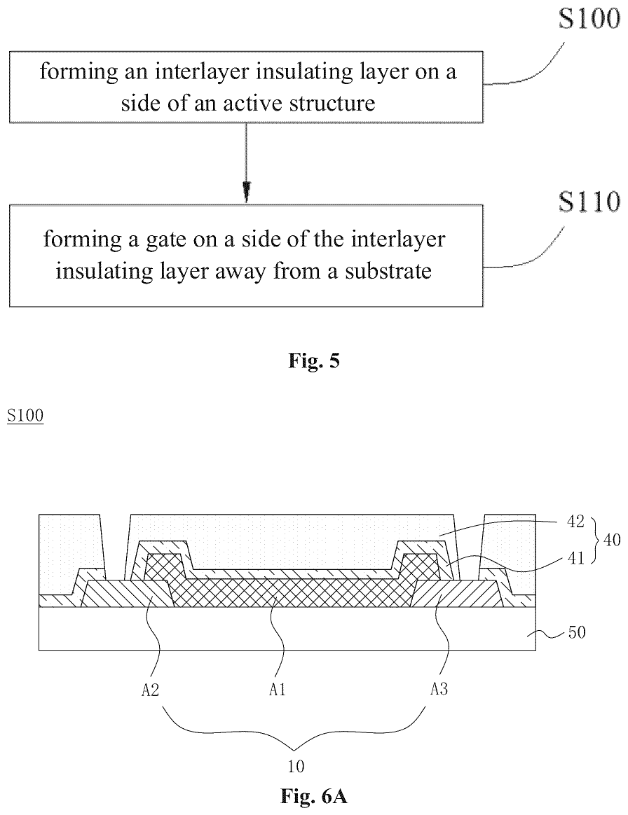

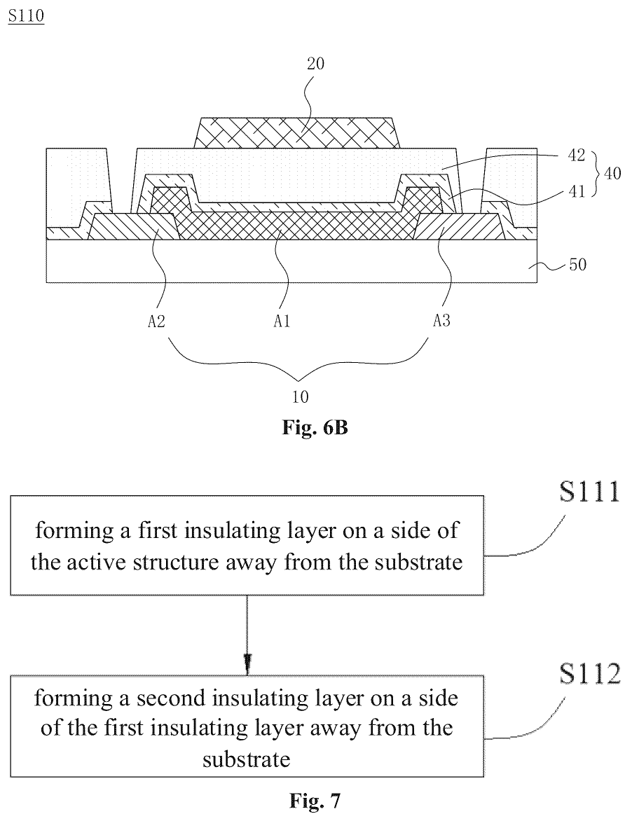

In a fourth aspect, referring to FIGS. 5 and 6, the embodiments of the present application provide a preparation method for a thin film transistor T, including S100 and S110.

S100: forming an interlayer insulating layer on a side of an active structure.

Referring to FIG. 6A, in step S100, the active structure 10 includes a source region A2, a drain region A3, and a channel region A1, the source region A2 and the drain region A3 are located on two sides of the channel region A1, the channel region A1 includes a metal oxide material, and a ratio of a number of indium atoms and a number of zinc atoms in the channel region A1 is a, and a>4. The interlayer insulating layer 40 is formed after the active structure 10, and the interlayer insulating layer 40 may protect the active structure 10 and reduce the adverse effects on the active structure 10 during the subsequent membrane layer preparation process. Here, the interlayer insulating layer 40 may have various forms, for example, the interlayer insulating layer 40 may include only one insulating structure, or may also include a variety of insulating structures, which is not limited by the embodiments of the present application.

In the related art, the ratio of the number of the indium atoms and the number of the zinc atoms in the channel region A1 is usually close to 1. However, in the embodiments of the present application, by setting a as not less than 4, the number of the indium atoms in the channel region A1 is increased, and thus the number of movable carriers is increased, so that the channel region A1 has a relative high carrier concentration. Further, on the basis of high carrier concentration, the carrier migration rate in the active structure 10 is improved, and thus the overall performance of the thin film transistor T is improved.

S110: forming a gate on a side of the interlayer insulating layer away from a substrate.

Referring to FIG. 6B, in step S110, the gate 20 is formed after the interlayer insulating layer 40, and in the thickness direction of the interlayer insulating layer 40, a projection of the gate 20 overlaps with a projection of the channel region A1. The presence of the interlayer insulating layer 40 can not only separate the gate 20 from the active structure 10, but also reduce the influence of the preparation process corresponding to the gate 20 on the active structure 10, so as to improve the structural reliability of the active structure 10.

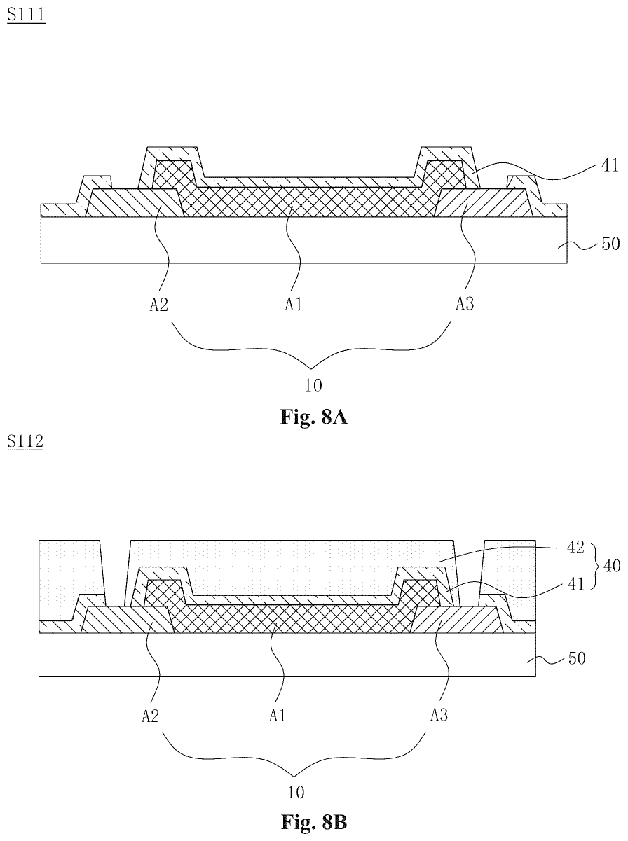

Referring to FIGS. 7 and 8, in some embodiments, step S110 includes S111 and S112.

S111: forming a first insulating layer on a side of the active structure away from the substrate.

Referring to FIG. 8A, in step S111, the first insulating layer 41 is a membrane layer in the interlayer insulating layer 40 which directly contacts the active structure 10. That is, the first insulating layer 41 is the membrane layer closest to the active structure 10. The material composition of the first insulating layer 41 is not limited by the embodiments of the present application. Optionally, the first insulating layer 41 includes at least one of silicon oxide and aluminum oxide.

S112: forming a second insulating layer on a side of the first insulating layer away from the substrate.

Referring to FIG. 8B, in step S112, the second insulating layer 42 is formed after the first insulating layer 41, and the presence of the first insulating layer 41 helps to reduce the influence of the preparation process of the second insulating layer 42 on the active structure 10, thereby improving the structural reliability of the active structure 10. The material composition of the second insulating layer 42 is not limited by the embodiments of the present application. Optionally, the second insulating layer 42 includes at least one of aluminum oxide and hafnium dioxide.

It should be noted that the specific implementation of the active structure 10, the first insulating layer 41, and the second insulating layer 42 is not limited by the embodiments of the present application.

Optionally, the active structure 10 is formed by atomic layer deposition or magnetron sputtering.

Optionally, the first insulating layer 41 is formed by chemical vapor deposition or atomic layer deposition.

Optionally, the second insulating layer 42 is formed by chemical vapor deposition or atomic layer deposition.

In some embodiments, the formation temperature of the first insulating layer 41 is less than the formation temperature of the second insulating layer 42, so that the density of the second insulating layer 42 is greater than the density of the second insulating layer 42.

Compared to the second insulating layer 42, the first insulating layer 41 is formed at a relatively low temperature condition. This design helps to reduce the influence of the preparation process corresponding to the first insulating layer 41 on the active structure 10, so as to reduce the risk of precipitation of the indium atoms on the surface of the active structure 10, and reduce the risk of carrier interface scattering. Optionally, the first insulating layer 41 is formed at a temperature condition of T1, and 80° C.≤T1≤200° C. For example, T1 can be 80° C., 100° C., 120° C., 160° C., 200° C., and the like.

Since the second insulating layer 42 is prepared under a relatively high temperature condition, the second insulating layer 42 can have a large density, thereby providing a good blocking effect on the active structure 10, reducing the risk of the water vapor and harmful substances penetrating into the active structure 10 via the second insulating layer 42 during subsequent membrane layer preparation, improving the stability of the thin film transistor T, and improving the service life of the thin film transistor T. Optionally, the second insulating layer 42 is formed at a temperature condition of T2, and T2>250° C. For example, T2 can be 250° C., 300° C., 350° C., 400° C., 450° C., and the like.

Although the implementations disclosed in the present application are described above, the foregoing is described only for the understanding of the present application and is not intended to limit the invention. Modifications and variations in forms and details may be made by any person skilled in the art related to the present application without departing from the gist and scope disclosed in the present application, but the protection scope of the present application is defined only by the scope of the appended claims.

The above are only specific implementations of the present application, those skilled in the art may clearly understand that the other alternatives of the above connections may be referred to the corresponding processes in the foregoing method embodiments, which is not repeated here for the convenience and brevity of the description. It should be understood that the protection scope of the present application is not limited to this, and any person skilled in the art can easily think of various equivalent modifications or replacements within the technical scope disclosed in the present application, and these modifications or replacements should all be covered within the scope of protection of the present application.

What is claimed is:

1. A thin film transistor comprising:
an active structure, comprising a source region, a drain region, and a channel region, the source region and the drain region being located on two sides of the channel region, wherein the channel region comprises a metal oxide material, a ratio of a number of indium atoms and a number of zinc atoms in the channel region is a, and a≥4;
a gate, being stacked and insulated by an interlayer insulating layer with the active structure, and in a thickness direction of the interlayer insulating layer, a projection of the gate overlapping with a projection of the channel region.

2. The thin film transistor of claim 1, wherein the interlayer insulating layer comprises a first insulating layer and a second insulating layer sequentially stacked in a direction away from the active structure;
a content of hydrogen atoms in the first insulating layer is b, and b>5%.

3. The thin film transistor of claim 2, wherein b≤10%.

4. The thin film transistor of claim 2, wherein a thickness of the first insulating layer is H1, and 5 nm≤H1≤20 nm;
the first insulating layer comprises at least one of silicon oxide and aluminum oxide.

5. The thin film transistor of claim 2, wherein a density of the first insulating layer is less than a density of the second insulating layer.

6. The thin film transistor of claim 5, wherein a content of hydrogen atoms in the second insulating layer is c, and c≤5%.

7. The thin film transistor of claim 5, wherein a thickness of the second insulating layer is H2, and 80 nm≤H2≤200 nm;
the second insulating layer comprises at least one of aluminum oxide and hafnium dioxide.

8. The thin film transistor of claim 1, wherein the channel region further comprises a plurality of X atoms, the X atoms are metal atoms, and a ratio of a number of the X atoms and the number of the indium atoms is d, and d≤0.1.

9. The thin film transistor of claim 8, wherein a ratio of the number of the X atoms and the number of the zinc atoms is e, and e≤0.5.

10. The thin film transistor of claim 8, wherein the plurality of X atoms comprise at least one of gallium atoms, tin atoms, tantalum atoms, and tungsten atoms.

11. A display panel comprising a thin film transistor, the thin film transistor comprising an active structure and a gate that are stacked and insulated by an interlayer insulating layer, the active structure comprising a source region, a drain region, and a channel region, the source region and the drain region being located on two sides of the channel region, and in a thickness direction of the interlayer insulating layer, a projection of the gate overlapping with a projection of the channel region;
wherein the channel region comprises a metal oxide material, a ratio of a number of indium atoms and a number of zinc atoms in the channel region is a, and a>4.

12. The display panel of claim 11, wherein the display panel further comprises a substrate, the thin film transistor is disposed on a side of the substrate, and the gate is disposed on a side of the active structure away from the substrate; or
the gate comprises a first sub-gate and a second sub-gate respectively arranged on two sides of the active structure in the thickness direction, and an orthographic projection of the first sub-gate on the substrate and an orthographic projection of the second sub-gate on the substrate both overlap with an orthographic projection of the same channel region on the substrate.

13. A display device comprising the display panel of claim 11.

14. A preparation method for a thin film transistor, comprising:
forming an interlayer insulating layer on a side of an active structure, the active structure comprising a source region, a drain region, and a channel region, the source region and the drain region being located on two sides of the channel region, the channel region comprising a metal oxide material, and a ratio of a number of indium atoms and a number of zinc atoms in the channel region is a, and a>4;
forming a gate on a side of the interlayer insulating layer away from a substrate, and in a thickness direction of the interlayer insulating layer, a projection of the gate overlapping with a projection of the channel region.

15. The preparation method of claim 14, wherein forming the interlayer insulating layer on the side of the active structure comprises:
forming a first insulating layer on a side of the active structure away from the substrate;
forming a second insulating layer on a side of the first insulating layer away from the substrate.

16. The preparation method of claim 15, wherein the active structure is formed by atomic layer deposition or magnetron sputtering.

17. The preparation method of claim 15, wherein the first insulating layer is formed by chemical vapor deposition or atomic layer deposition;
the second insulating layer is formed by chemical vapor deposition or atomic layer deposition.

18. The preparation method of claim 15, wherein a formation temperature of the first insulating layer is less than a formation temperature of the second insulating layer, so that a density of the second insulating layer is greater than a density of the first insulating layer.

19. The preparation method of claim 18, wherein forming the first insulating layer on the side of the active structure away from the substrate comprises forming the first insulating layer at a temperature condition of T1, wherein 80° C.<T1≤200° C.

20. The preparation method of claim 18, wherein forming the second insulating layer on the side of the first insulating layer away from the substrate comprises forming the second insulating layer at a temperature condition of T2, wherein T2>250° C.
